(19) United States
(12) Patent Application Publication
(10) Pub. No.: US 2011/0141703 A1
(43) Pub. Date: Jun. 16, 2011

(54) MOUNT AND ELECTRONIC DEVICE

(75) Inventors: Tomoko KITAMURA, Ome-shi (JP); Tomohiro HAMADA, Tachikawa-shi (JP); Hideo SHIRASAKA, Ome-shi (JP)

(73) Assignee: KABUSHIKI KAISHA TOSHIBA, Tokyo (JP)

(21) Appl. No.: 12/886,266

(22) Filed: Sep. 20, 2010

(30) Foreign Application Priority Data
Dec. 16, 2009 (JP) 2009-285428

(51) Int. Cl. H05K 7/00; F16M 13/02

(52) U.S. Cl. 361/736; 248/222.14

(57) ABSTRACT

According to one embodiment, an electronic device includes a device housing, a circuit board, a module, and a projection. The electronic device includes a base in which a containing portion is provided. The circuit board is housed in the device housing. The module is housed in the containing portion of the device housing and electrically connected to the circuit board. The projection is provided with a supporting part and an opening portion. The supporting part projects from the module and is supported by the base. The opening is positioned between the supporting part and the module.

### CROSS-REFERENCE TO RELATED APPLICATIONS

This application is based upon and claims the benefit of priority from Japanese Patent Application No. 2009-285428, filed Dec. 16, 2009; the entire contents of which are incorporated herein by reference.

### FIELD

Embodiments described herein relate generally to a mount which fixes modules of an electronic device to a housing, and an electronic device comprising such a mount.

### BACKGROUND

The need to reduce the weight and thickness of electronic equipment such as portable computers has been increasing to provide convenience for carrying. This kind of equipment houses various modules such as a hard disk drive (HDD), an optical disk drive (ODD), and a liquid crystal display panel. These modules have connectors to which cables are attached to allow interconnection with other components such as a motherboard.

The modules are secured within the equipment housing by means of mounts. For example, Jpn. Pat. Appln. KOKAI Publication No. 6-44761 discloses mounts which are fixed to a hard disk drive and a housing with screws, each mount comprising an elastic damper which prevents vibration from reaching the drive.

If an electronic device is jarred by being dropped, shock readily concentrates in the module connectors. To dissipate this shock, the modules are fixed to the housing so there is slight play where their connectors are situated, while elsewhere they sit firmly. This requires at least two kinds of mounts: one providing a firm seating, and one allowing slight play through the use of a special screw threaded only at the tip. The need for such a screw, however, increases the number of types of component involved in assembly.

### BRIEF DESCRIPTION OF THE DRAWINGS

A general architecture that implements the various feature of the embodiments will now be described with reference to the drawings. The drawings and the associated descriptions are provided to illustrate the embodiments and not to limit the scope of the invention.

FIG. 1 is an exemplary perspective view showing a portable computer according to the first embodiment.

FIG. 2 is an exemplary plan view showing the portable computer according to the first embodiment when viewed from below.

FIG. 3 is an exemplary plan view showing the base according to the first embodiment.

FIG. 4 is an exemplary perspective view showing the HDD module according to the first embodiment.

FIG. 5 is an exemplary side view showing a part of the mount according to the first embodiment.

FIG. 6 is an exemplary cross-sectional view of the base shown in FIG. 3, taken along the line F6-F6.

FIG. 7 is an exemplary cross-sectional view of the portion enclosed with the circle A of the base shown in FIG. 6.

FIG. 8 is an exemplary plan view showing the base according to the second embodiment.

FIG. 9 is an exemplary plan view showing the inside of the main housing according to the third embodiment.

FIG. 10 is an exemplary perspective view showing the ODD module according to the third embodiment.

FIG. 11 is an exemplary perspective view showing the mount according to the third embodiment.

FIG. 12 is an exemplary cross-sectional view of the ODD module, base, and mount according to the third embodiment.

FIG. 13 is an exemplary plan view showing the inside of the display housing according to the fourth embodiment.

FIG. 14 is an exemplary enlarged plan view of the portion enclosed with the circle E of the display unit shown in FIG. 13.

### DETAILED DESCRIPTION

Various embodiments will be described hereinafter with reference to the accompanying drawings.

In general, according to one embodiment, an electronic device includes a device housing, a circuit board, a module, and a projection. The electronic device includes a base in which a containing portion is provided. The circuit board is housed in the device housing. The module is housed in the containing portion of the device housing and electrically connected to the circuit board. The projection is provided with a supporting part and an opening portion. The supporting part projects from the module and is supported by the base. The opening is positioned between the supporting part and the module.

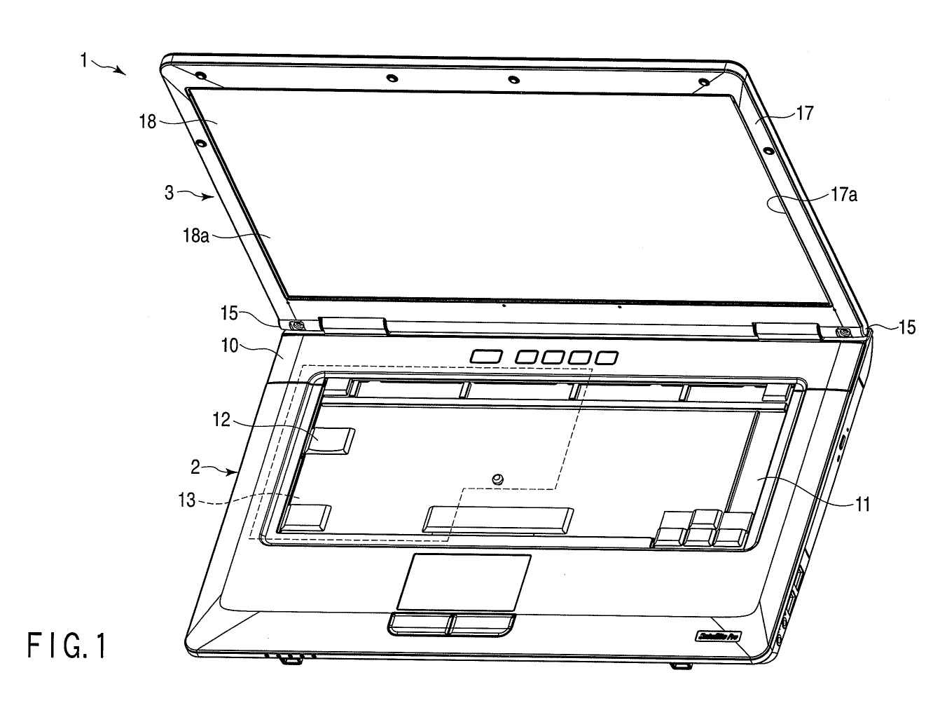

A description will now be given of the first embodiment, with reference to FIGS. 1 to 7.

FIG. 1 is a perspective view showing a portable computer 1 except a part of keys of a keyboard. As shown in FIG. 1, a portable computer 1 which is an example of an electronic device includes a computer main body 2 and a display unit 3. The computer main body 2 includes a main housing 10 which is an example of a device housing and is shaped like a flat box. A keyboard installation portion 11 is provided on the upper surface of the main housing 10, and a keyboard 12 is mounted on the keyboard installation portion 11. A circuit board 13 which is, for example, a motherboard including a CPU is housed inside the main housing 10.

The display unit 3 is connected to the rear end of the computer main body 2 by means of a pair of hinge portions 15. The display unit 3 is pivotable about the hinge portions 15 between a closed position where the display unit 3 is laid parallel to the computer main body 2 and an open position where the display unit 3 is raised relative to the computer main body 2.

The display unit 3 includes a display housing 17 which is shaped like a flat box and a display module 18 which is housed in the display housing 17. The display module 18 is, for example, a liquid crystal display. A display opening 17a is positioned on the front surface of the display housing 17, and a screen 18a of the display module 18 is exposed from the display unit 3 by the display opening 17a.

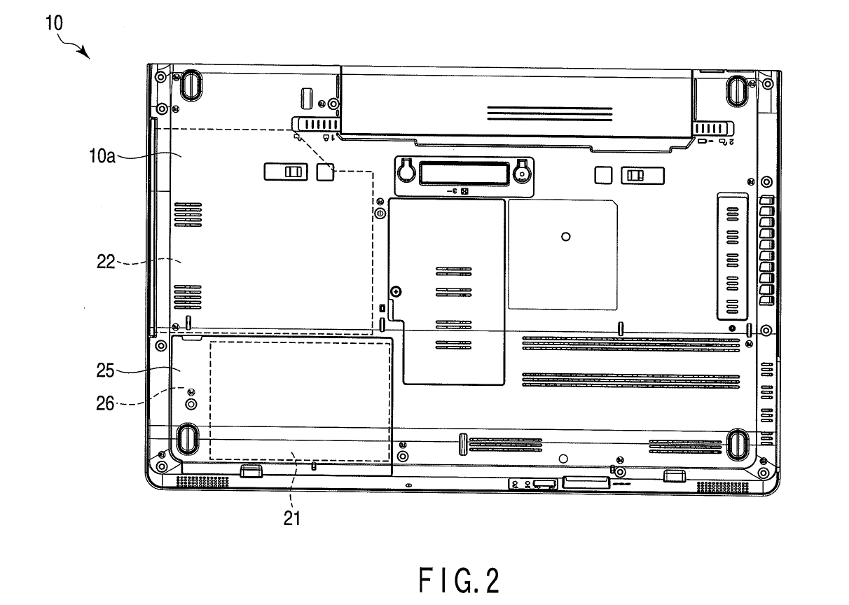

FIG. 2 is a plan view showing the portable computer 1 when viewed from below. As shown in FIG. 2, the main housing 10 includes an HDD module 21 and an ODD module 22. HDD module 22 is an example of a module. Each of the HDD module 21 and the ODD module 22 is electrically connected to the circuit board 13.

The main housing 10 comprises a cover 25 and a base 26. The base 26 is covered with the cover 25. The base 26 is provided in the inside of the main housing 10.

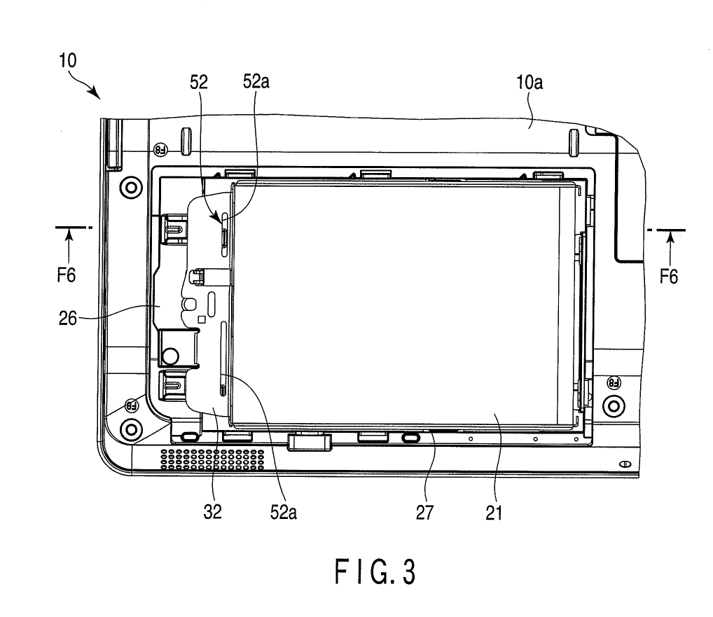

FIG. 3 is a plan view showing the base 26 in which the cover 25 is removed. As shown in FIG. 3, the base 26 is provided with a containing portion 27 which houses the HDD module 21. The containing portion 27 is sunk into the base 26.

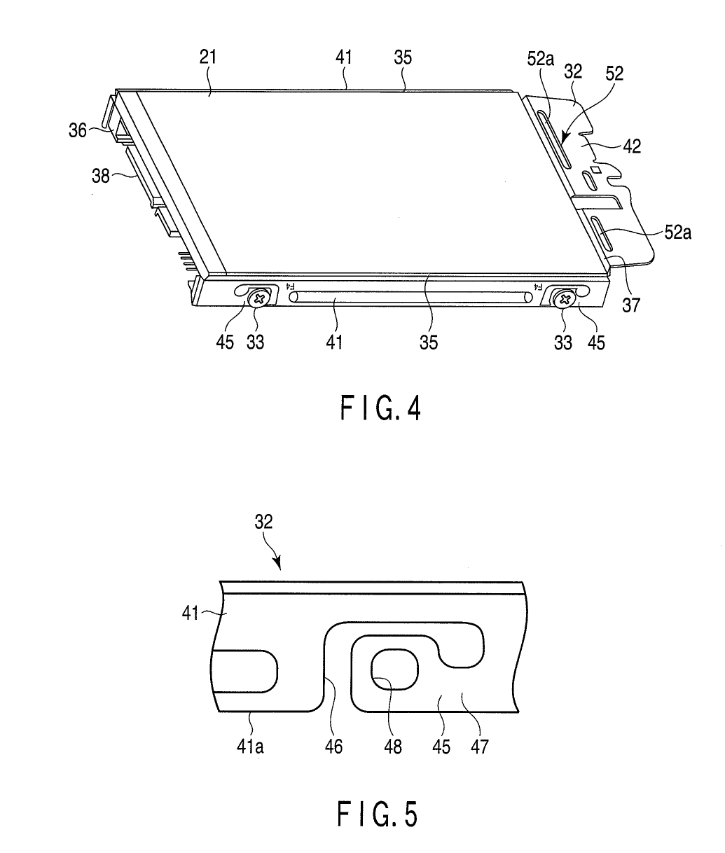

FIG. 4 is a perspective view showing the HDD module 21. As shown in FIG. 4, a mount 32 which is an example of a projection is attached to the HDD module 21 by means of a plurality of first screws 33.

The HDD module 21 includes a pair of side portions 35, a front side portion 36, a rear side portion 37 and a connector 38. The rear side portion 37 is an example of a side of module. The rear side portion 37 is opposed to the front side portion 37. The connector 38 is provided on the front side portion 36, and cables used for power supply and data transfer are attached thereto. The cable for data transfer is attached to the connector 38 to allow electrical interconnection between the HDD module 21 and the circuit board 13.

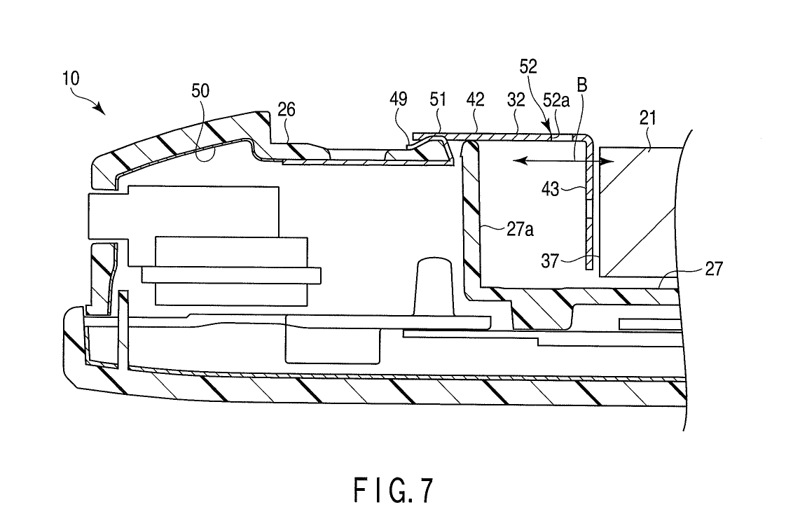

The mount 32 is formed, for example, by bending a plate-like metallic material. The mount 32 includes a pair of first portions 41, a second portion 42 and a middle portion 43 (shown in FIG. 7) which are integrally formed as one-body.

The middle portion 43 is positioned between the first portions 41 and the second portion 42 and along the rear side portion 37 of the HDD module 21. Each of the pair of first portions 41 is positioned orthogonal to the middle portion 43 and along each of the pair of side portions 35. The second portion 42 is positioned orthogonal to the middle portion 43 and opposed to the HDD module 21.

FIG. 5 is a side view showing a part of one of the first portions 41. The first portion 41 includes a plurality of installation parts 45. Each of the installation parts 45 is defined by a substantially L-shaped slit 46. The slit 46 is formed from a side edge 41a of the first portion 41 into the inside of the first portion 41. Each installation part 45 includes a narrow portion 47 and is provided with a first screw hole 48 through which a first screw is inserted.

As shown in FIG. 4, a plurality of first screws 33 are driven into the HDD module 21 through the first screw holes 48 so that the first portions 41 of the mount 32 are fixed to the HDD module 21.

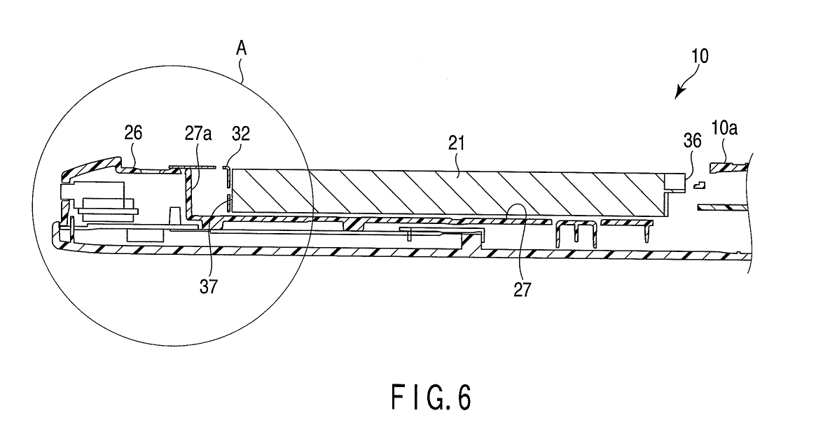

FIG. 6 is a cross-sectional view of the HDD module 21 housed in the containing portion 27, taken along the line F6-F6 shown in FIG. 3. FIG. 7 is a cross-sectional view of the portion enclosed with the circle A of the base shown in FIG. 6. As shown in FIG. 7, the base 26 comprises a ground portion 49 which extends from the inside of the main housing 10 to the base 26.

The main housing 10 comprises a shielding layer 50 on the inner surface thereof. The shielding layer 50 is a metallic thin film formed, for example, by sputtering. The shielding layer 50 prevents electromagnetic waves generated from circuit components or the like housed in the main housing 10 from externally leaking through the main housing 10. The shielding layer 50 also prevents externally generated electromagnetic waves from adversely affecting the circuit components in the main housing 10. The shielding layer 50 is electrically connected to the ground portion 49.

The second portion 42 of the mount 32 includes a supporting part 51 which is supported by the base 26. The supporting part 51 is brought into contact with the ground portion 49 of the base 26.

The second portion 42 is provided with an opening portion 52 which includes two openings 52a. The opening portion 52 is positioned between the supporting part 51 and the HDD module 21. To be more specific, the opening portion 52 is positioned between the rear side portion 37 of the HDD module 21 and a sidewall 27a of the containing portion 27, which is opposed to the rear side portion 37, and positioned close to the rear side portion 37.

As shown in FIG. 4, the two openings 52a are elongated parallel to the rear side portion 37 of the HDD module 21. The opening portion 52 is provided between the supporting part 51 and the HDD module 21.

In the portable computer 1 having the above structure, the opening portion 52 is formed between the supporting part 51 and the HDD module 21. Namely, the opening portion 52 is positioned between the supporting part 51 supported by the base 26 and the HDD module 21. In this structure, the second portion 42 of the mount 32 is elastically movable along axis B shown in FIG. 7 relative to the first portions 41 fixed to the HDD module 21. Axis B is the axis along which the second portion 42 moves perpendicularly towards or away from the HDD module 21.

If the portable computer 1 is jarred, for example, by being dropped, the second portion 42 elastically moves relative to the first portions 41, and the HDD module 21 therefore elastically moves relative to the base 26. This structure dissipates the shock transmitted to the HDD module 21 from the main housing 10 and prevents stress from being concentrated on the connector 38 of the HDD module 21.

The openings 52a are elongated parallel to the rear side portion 37 of the HDD module 21. Namely, the openings 52a extend perpendicularly to axis B along which the second portion 42 is elastically moved relative to the first portions 41. This structure helps the second portion 42 elastically move relative to the first portions 41.

Further, stress concentration on the connector 38 of the HDD module 21 can be prevented merely by adopting the mount 32. This decreases the number of types of component involved in assembly. In addition, a conventional screw is adoptable to the first screw 33 which fixes the HDD module 21 to the mount 32, thereby decreasing the manufacturing cost for the portable computer 1.

The supporting part 51 is brought into contact with the ground portion 49 of the base 26. In this structure, the mount 32 can be grounded to the shielding layer 50 via the ground portion 49. This eliminates the need to employ an additional conductive member, and decreases the number of types of component. Accordingly, the manufacturing cost for the portable computer 1 can be decreased.

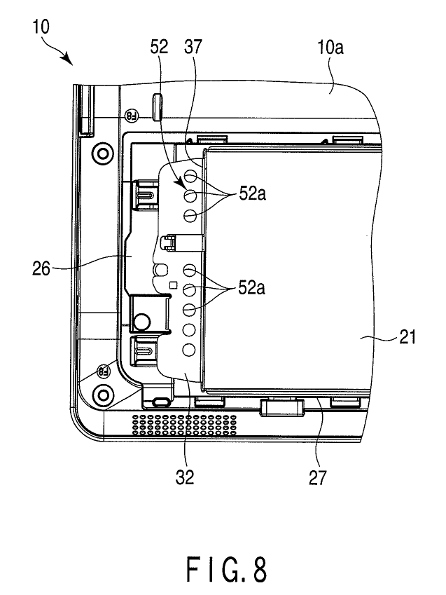

A description will now be given of a portable computer 1 according to the second embodiment with reference to FIG. 8. The structural components or elements that are similar to those of the first embodiment will be denoted by the same reference symbols, and a repetitive description of such components or elements will be omitted.

FIG. 8 is a plan view showing a base 26 in which a cover 25 is removed. As shown in FIG. 8, the shape of openings 52a according to the second embodiment is circular, which is different from the first embodiment. In the second embodiment, a plurality of openings 52a are arranged in a line parallel to a rear side portion 37 of an HDD module 21.

In the portable computer 1 having the above structure, an opening portion 52 which has openings 52a is positioned between a supporting part 51 and the HDD module 21, as same as the first embodiment. In this structure, if the portable computer 1 is jarred, for example, by being dropped, a second portion 42 elastically moves relative to first portions 41. This structure dissipates the shock transmitted to the HDD module 21 from a main housing 10 and prevents stress from being concentrated on a connector 38 of the HDD module 21.

The shape of openings 52a is not limited to elongated or circular shape, but may be oval, rectangle or other shapes, if extending parallel to the rear side portion 37 of the HDD module 21. In addition, the opening portion 52 may have only one opening 52a.

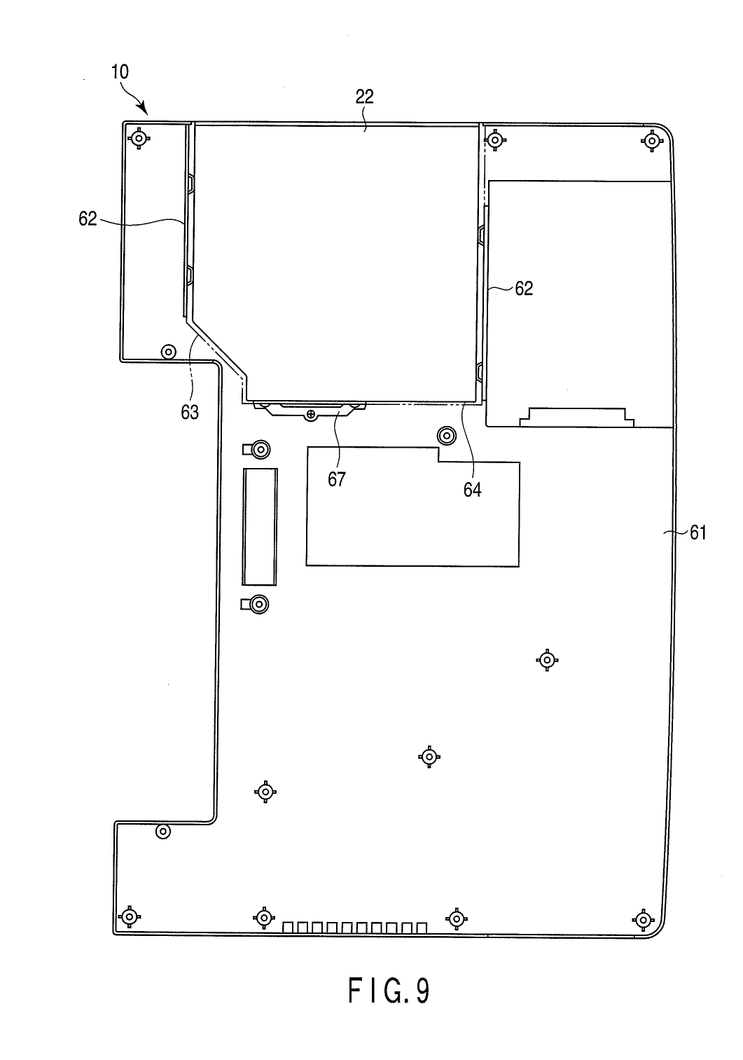

A description will now be given of a portable computer 1 according to the third embodiment with reference to FIGS. 9-12. The structural components or elements that are similar to those of the first embodiment will be denoted by the same reference symbols, and a repetitive description of such components or elements will be omitted.

FIG. 9 is a plan view showing the inside of a main housing 10. As shown in FIG. 9, the main housing 10 includes a base 61 and a pair of ribs 62. The base 61 is housed within the main housing 10. The base 61 is an example of a base and an example of a bottom surface of the device housing. The pair of ribs 62 projects from the base 61 toward the inside of the main housing 10.

The base 61 is provided with a containing portion 63 which is provided between the pair of ribs 62. The containing portion 63 houses an ODD module 22. The ODD module 63 is an example of a module.

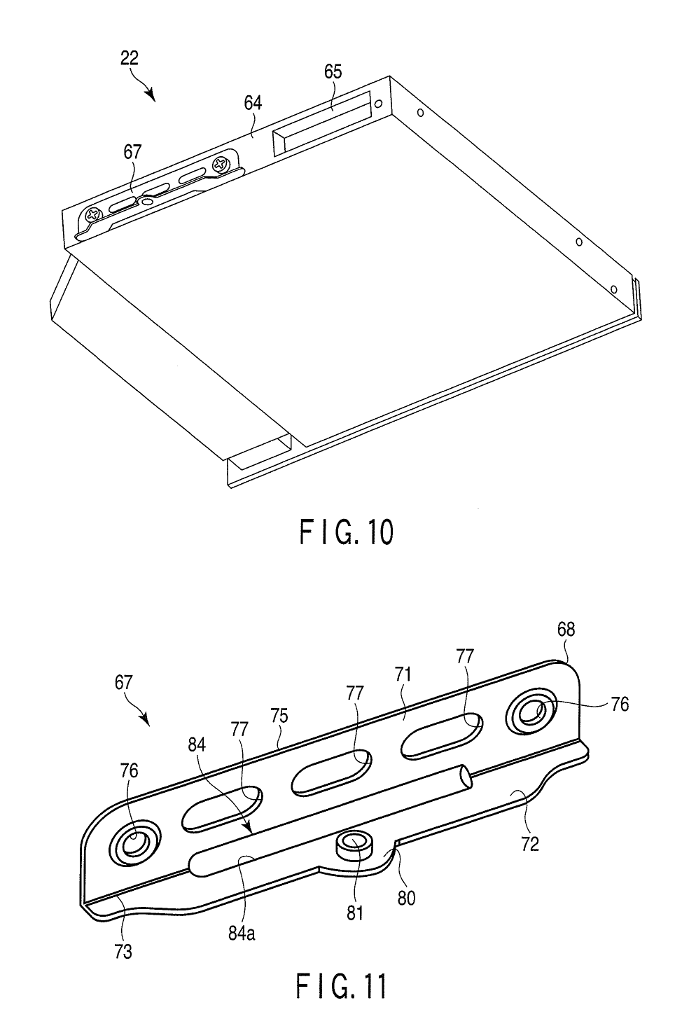

FIG. 10 is a perspective view showing the ODD module 22 according to the third embodiment when viewed from below. As shown in FIG. 10, the ODD module 22 includes a rear side 64 and a connector 65. The rear side 64 is an example of a side of a module. The connector 65 is provided on the rear side 64, and cables used for power supply and data transfer are attached thereto. The cable for data transfer is attached to the connector 65 to allow electrical interconnection between the ODD module 22 and a circuit board 13.

A mount 67 is attached to the rear side 64 of the ODD module 22. The mount 67 is an example of a mount and an example of a projection. The mount 67 is formed, for example, by bending a plate-like metallic material. The mount 67 comprises a mount main body 68 which is used to attach the ODD module 22 to the base 61.

FIG. 11 is a perspective view showing the mount 67. As shown in FIG. 11, the mount main body 68 comprises a module fixing portion 71, a device housing fixing portion 72 and a corner portion 73. The module fixing portion 71 is an example of a module fixing portion and an example of a first portion. The device housing fixing portion 72 is an example of a device housing fixing portion and an example of a second portion. The module fixing portion 71, device housing fixing portion 72 and corner portion 73 are integrally formed as one-body.

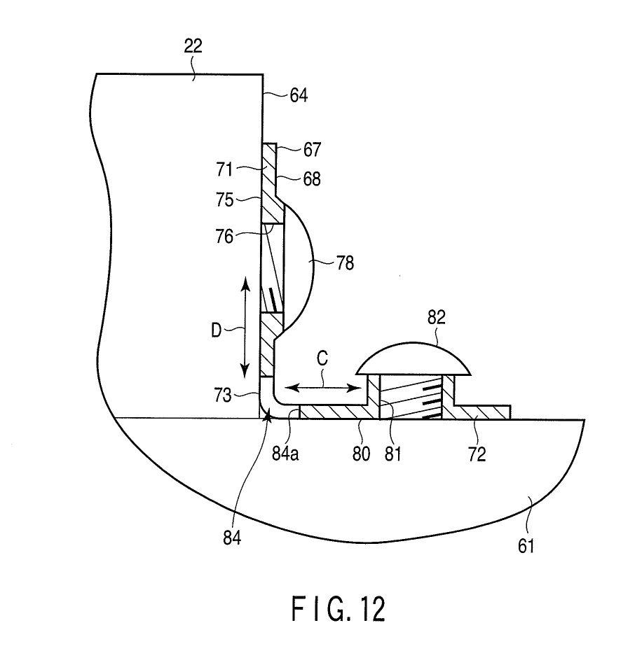

FIG. 12 shows the ODD module 22 and the base 61 fixed by means of the mount 67. The module fixing portion 71 includes a connecting portion 75. As shown in FIG. 12, the connecting portion 75 is brought into contact with the rear side 64 of the ODD module 22.

As shown in FIG. 11, the module fixing portion 71 includes a pair of first screw holes 76 and a plurality of punch holes 77. One of a pair of first screw holes 76 is arranged at each longitudinal end of the module fixing portion 71. The plurality of punch holes 77 are provided for reducing the weight of the mount 67.

As shown in FIG. 12, a pair of first screws 78 are inserted into the pair of first screw holes 76. The first screws 78 are driven into the ODD module 22 through the first screw holes 76 so that the connecting portion 75 is fixed to the ODD module 22.

The device housing fixing portion 72 extends perpendicularly to the module fixing portion 71. Namely, the device housing fixing portion 72 is opposed to the ODD module 22. As shown in FIG. 12, the device housing fixing portion 72 includes a supporting part 80 which is supported by the base 61.

As shown in FIG. 11, a second screw hole 81 is provided in the device housing fixing portion 72. The second screw hole 81 is provided at the longitudinal center of the device housing fixing portion 72.

As shown in FIG. 12, a second screw 82 is inserted into the second screw hole 81. The second screw 82 is an example of a second screw and an example of a fastener. The second screw 82 is driven into the base 61 through the second screw hole 81 so that the supporting part 80 is fixed to the base 61. Namely, the mount main body 68 is fixed to the base 61.

The corner portion 73 is defined between the module fixing portion 71 and the device housing fixing portion 72. The corner portion 73 is formed by bending a metallic material, and provided with an opening portion 84.

As shown in FIG. 11, the opening portion 84 spans the boundary between the module fixing portion 71 and the device housing fixing portion 72. The opening portion 84 includes an opening 84a which is elongated parallel to the rear side 64 of the ODD module 22.

In the portable computer 1 having the above structure, the opening portion 84 is formed between the supporting part 80 and the ODD module 22. In addition, the opening portion 84 spans the boundary between the module fixing portion 71 and the device housing fixing portion 72. In this structure, the device housing fixing portion 72 of the mount 67 is elastically movable along axes C and D shown in FIG. 12 relative to the module fixing portion 71 fixed to the ODD module 22. Axis C is the axis along which the mount 67 perpendicularly moves towards or away from the ODD module 22. Axis D is the axis along which the mount 67 perpendicularly moves towards or away from the base 61.

If the portable computer 1 is jarred, for example, by being dropped, the device housing fixing portion 72 elastically moves relative to the module fixing portion 71, and the ODD module 22 therefore elastically moves relative to the base 26. This structure dissipates the shock transmitted to the ODD module 22 from the main housing 10 and prevents stress from being concentrated on the connector 65 of the ODD module 22.

The opening 84a is elongated parallel to the rear side 64 of the ODD module 22. Namely, the opening 84a extends perpendicularly to the axes C and D along which the device housing fixing portion 72 is elastically moved relative to the module fixing portion 71. This structure helps the device housing fixing portion 72 elastically move relative to the module fixing portion 71.

Further, stress concentration on the connector 65 of the ODD module 22 can be prevented merely by adopting the mount 67. This decreases the number of types of component involved in assembly. In addition, a conventional screw is adoptable to the first screw 78 which fixes the ODD module 22 to the mount 67, thereby decreasing the manufacturing cost for the portable computer 1.

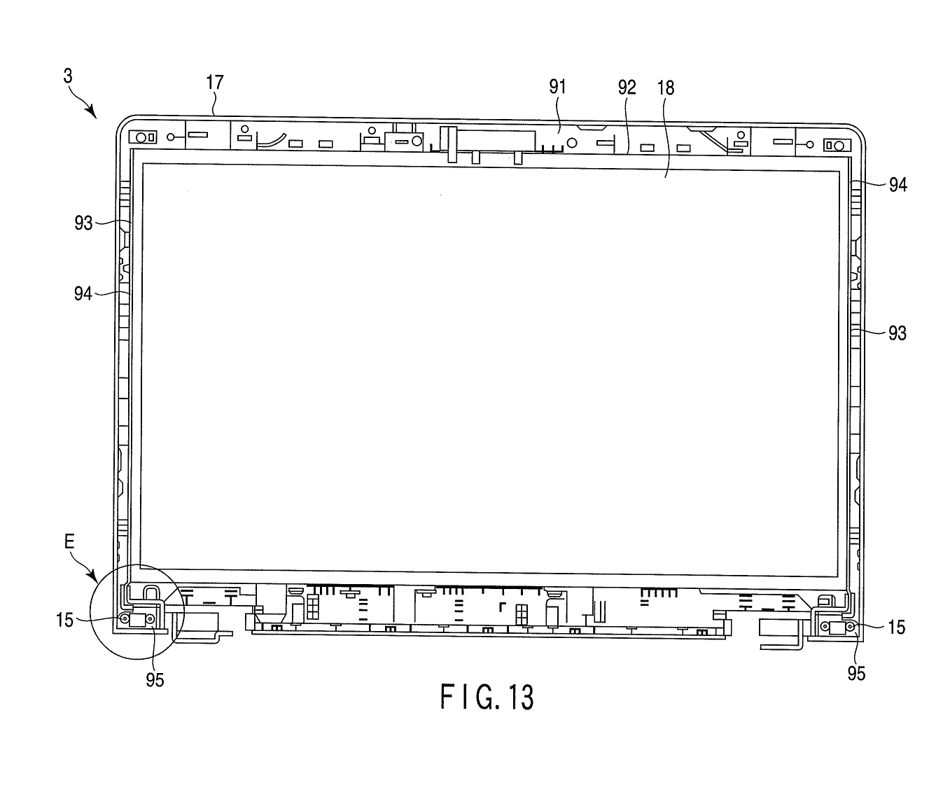

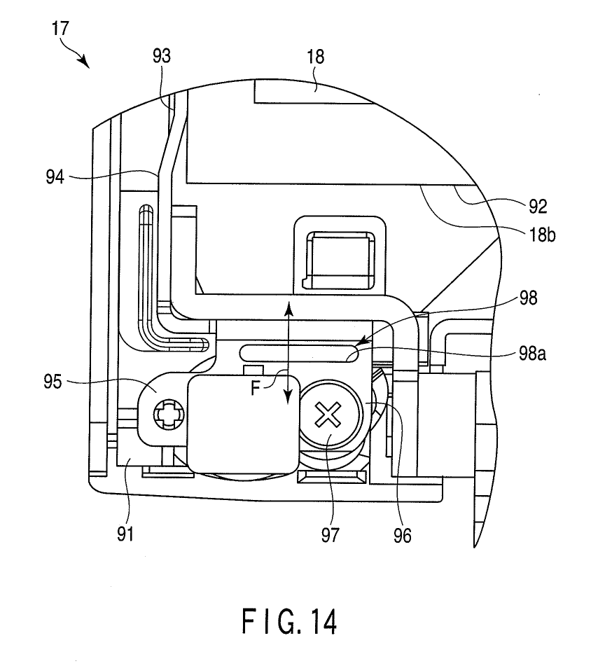

A description will now be given of a portable computer 1 according to the fourth embodiment with reference to FIGS. 13 and 14. The structural components or elements that are similar to those of the first embodiment will be denoted by the same reference symbols, and a repetitive description of such components or elements will be omitted.

FIG. 13 is a plan view showing the inside of a display unit 3. A display housing 17 comprises a base 91. The display housing 17 is an example of a device housing. The base 91 is provided in the inside of the display housing 17. The base 91 is provided with a containing portion 92, the containing portion 92 being defined by a plurality of ribs projecting from the base 91.

As shown in FIG. 13, the containing portion 92 houses a display module 18. The display module 18 is an example of a module. The display module 18 is electrically connected to a circuit board 13.

A pair of mounts 93 which is an example of a projection is fixed to the display module 18. Each of the mounts 93 includes a first portion 94 and a second portion 95. The first portion 94 is fixed to the display module 18. The second portion 95 projects opposed to the display module 18.

FIG. 14 is an enlarged plan view of the portion enclosed with the circle E of the display unit 3 shown in FIG. 13. As shown in FIG. 14, the second portion 95 includes a supporting part 96. The supporting part 96 is supported by the base 91. The supporting part 96 is fixed to the base by means of a fixing screw 97 which is an example of a fastener.

The second portion 95 is provided with an opening portion 98 between the supporting part 96 and the display module 18. The opening portion 98 includes an opening 98a which is elongated parallel to the side 18b of the display module 18.

In the portable computer 1 having the above structure, the opening portion 98 is formed between the supporting part 96 and the display module 18. In this structure, the second portion 95 of the mount 93 is elastically movable along axis F shown in FIG. 14 relative to the first portion 94 fixed to the display module 18. Axis F is the axis along which the second portion 95 perpendicularly moves towards or away from the display module 18.

The present invention is not limited to the above embodiments and may be remodeled into various different versions as long as the essence of the invention does not fall out of the scope thereof. In addition, the module is not limited to ODD, HDD, or display module and may be other modules such as a pointing device.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A mount comprising:
a mount main body configured to attach a module to a bottom surface of a device housing,
wherein the mount main body comprises,
a module fixing portion comprising a connecting portion in contact with a side of the module, the module fixing portion comprising a plurality of first screw holes through which a plurality of first screws fixing the module to the connecting portion are inserted;
a device housing fixing portion which extends perpendicularly to the module fixing portion, the device housing fixing portion comprising a second screw hole through which a second screw fixing the mount main body to the bottom surface of the device housing is inserted; and
a corner portion defined between the module fixing portion and the device housing fixing portion, the corner portion comprising an opening which spans the boundary between the module fixing portion and the device housing fixing portion and is elongated parallel to the side of the module.

2. An electronic device comprising:
a device housing comprising a base comprising a containing portion;
a circuit board housed in the device housing;
a module housed in the containing portion of the device housing and electrically connected to the circuit board; and
a projection projecting from the module, the projection comprising a supporting portion supported by the base, the supporting portion comprising an opening portion between the supporting portion and the module.

3. The electronic device of claim 2, wherein the opening portion comprises an opening which is elongated parallel to the side of the module.

4. The electronic device of claim 2, wherein the projection comprises a first portion fixed to the module and a second portion comprising the supporting portion and the opening portion, wherein the first portion and the second portion are integrally formed as one-body.

5. The electronic device of claim 4, wherein the opening portion spans a boundary between the first and the second portions.

6. The electronic device of claim 2, wherein the supporting portion is fixed to the base with a fastener.

7. The electronic device of claim 2, wherein the containing portion is sunk into the base and comprises a sidewall opposed to the side of the module, and the opening portion is positioned between the side of the module and the sidewall.

8. The electronic device of claim 7, wherein the opening portion is formed close to the side of the module.

9. The electronic device of claim 2, wherein the base comprises a ground portion in contact with the supporting portion.

10. The electronic device of claim 2, wherein the opening portion comprises a plurality of openings, the plurality of openings being arranged in a line parallel to the side of the module.
